(19) United States
(12) Patent Application Publication
(10) Pub. No.: US 2023/0179197 A1
(43) Pub. Date: Jun. 8, 2023

(54) GATE DRIVE DEVICE AND LOAD POWER SUPPLY CIRCUIT

(71) Applicant: DENSO CORPORATION, Kariya-city (JP)

(72) Inventor: Atsushi KOBAYASHI, Kariya-city (JP)

(21) Appl. No.: 18/160,721

(22) Filed: Jan. 27, 2023

Related U.S. Application Data
(63) Continuation of application No. PCT/JP2021/029906, filed on Aug. 16, 2021.

(30) Foreign Application Priority Data
Sep. 4, 2020 (JP) 2020-149045

(51) Int. Cl. H03K 17/082; H03K 17/60

(52) U.S. Cl. CPC H03K 17/0826; H03K 17/60

(57) ABSTRACT

A gate drive device for a switching element includes: a surge voltage detection circuit for detecting a surge voltage when the switching element is turned off; a delay circuit for outputting a timing signal when a predetermined delay time elapses after a turn-off start signal is input; and a driving current output unit for starting to supply a first gate drive current to the switching element when the turn-off start signal is input, and for starting to supply a second gate drive current to the switching element when the delay circuit outputs the timing signal. The delay circuit is configured to change and set the delay time when the surge voltage is different from a target value.

### CROSS REFERENCE TO RELATED APPLICATIONS

The present application is a continuation application of International Patent Application No. PCT/JP2021/029906 filed on Aug. 16, 2021, which designated the U.S. and claims the benefit of priority from Japanese Patent Application No. 2020-149045 filed on Sep. 4, 2020. The entire disclosures of all of the above applications are incorporated herein by reference.

### TECHNICAL FIELD

The present disclosure relates to a gate drive device and a load power supply circuit.

### BACKGROUND

AGC (i.e., Active Gate Control) technology has been proposed as a control mode for driving and controlling a gate-drive semiconductor switching element. Various methods have been proposed as such AGC technology, but the difficulties remain in practical use.

### SUMMARY

According to an example, a gate drive device for a switching element may include: a surge voltage detection circuit for detecting a surge voltage when the switching element is turned off; a delay circuit for outputting a timing signal when a predetermined delay time elapses after a turn-off start signal is input; and a driving current output unit for starting to supply a first gate drive current to the switching element when the turn-off start signal is input, and for starting to supply a second gate drive current to the switching element when the delay circuit outputs the timing signal. The delay circuit is configured to change and set the delay time when the surge voltage is different from a target value.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a diagram showing an electric configuration according to a first embodiment;

FIG. 2 is a diagram showing an electrical configuration of a surge voltage detection circuit;

FIG. 3 is a diagram for explaining the operation of surge voltage detection,

FIG. 4 is a diagram for explaining the operation of delay time control;

FIG. 5 is a flow chart showing delay time control;

FIG. 6 is a diagram for explaining delay time adjustment;

FIG. 7 is a diagram showing a delay time setting condition;

FIG. 8 is a diagram for explaining the operation when the power supply voltage increases;

FIG. 9 is a diagram for explaining active gate control;

FIG. 10 is a diagram for explaining a turn-off waveform;

FIG. 11 is a diagram showing the relationship between the surge voltage and the turn-off loss;

FIG. 12 is a diagram for explaining the surge voltage and the turn-off loss;

FIG. 13 is a diagram for explaining the relationship between the delay time setting and the characteristics;

FIG. 14 is a timing chart showing the relationship between the surge voltage and the turn-off loss;

FIG. 15 is a diagram illustrating an example of a delay circuit according to a second embodiment;

FIG. 16 is a diagram showing a first example of a delay circuit;

FIG. 17 is a diagram showing a second example of a delay circuit;

FIG. 18 is a diagram showing a third example of a delay circuit; and

FIG. 19 is a diagram showing a fourth example of a delay circuit.

### DETAILED DESCRIPTION

The following difficulties relating to the AGC remain in practical use.

First, the switching timing may shift due to variations in the characteristics and operating conditions of the semiconductor switching element as a control target, and therefore, a difficulties may arise such that the surge voltage exceeds the withstand voltage and/or the effect of the loss reduction decreases.

Secondly, since it is impossible to determine whether or not the surge voltage exceeds the withstand voltage in the configuration that does not monitor the surge voltage, it may be difficult to perform reliable control.

The present embodiments have been made in consideration of the above circumstances, and its purpose is to provide a gate drive device and a load power supply circuit which can be controlled so as to eliminate a switching timing shift due to variations in the characteristics and variations in the operating conditions of the semiconductor switching element as the control target and to prevent the surge voltage from exceeding the withstand voltage.

The gate drive device according to the present embodiments drives and controls a gate when a gate drive type switching element is driven to turn on or off.

The gate drive device includes: a surge voltage detection circuit for detecting, as a surge voltage, a peak voltage between a drain and a source or a voltage between a collector and an emitter of the switching element when the switching element is turned off; a delay circuit for outputting a timing signal when a predetermined delay time elapses after a turn-off start signal is input; and a driving current output unit for starting to supply a first gate drive current to the gate of the switching element when the turn-off start signal is input, and for starting to supply a second gate drive current lower than the first gate drive current to the gate when the delay circuit outputs the timing signal. The delay circuit is configured to change and set the delay time when the surge voltage detected by the surge voltage detection circuit is different from a target value.

By adopting the above configuration, when a turn-off start signal is given, the delay circuit starts measuring the delay time, and the drive current output unit supplies the first gate drive current for turn-off to the gate of the switching element to start performing the turn off operation. After that, when the delay time elapses and the timing signal is given from the delay circuit, the drive current output unit switches so that the second gate drive current for turn-off flows at the gate of the switching element.

As a result, the switching element is turned off by discharging the gate charge. At this time, the voltage of the switching element provides a surge voltage that temporarily exceeds the power supply voltage at the time of turn-off. This surge voltage is detected by a surge voltage detection circuit as the peak voltage of the drain-source voltage or the collector-emitter voltage when the switching element is turned off. When the surge voltage is different from the predetermined target value, the delay circuit changes and sets the delay time so as to approach the surge voltage to the predetermined target value, and inputs the timing signal to the drive current output unit.

In this manner, by changing and setting the delay time by the delay circuit, the surge voltage at the time when the switching element is turned off can be set to the target value. As a result, the turn-off loss can be suppressed by performing the turn-off operation in a short time with a high first gate drive current while maintaining the condition that the surge voltage at the time of turn-off of the switching element does not exceed the withstand voltage.

### First Embodiment

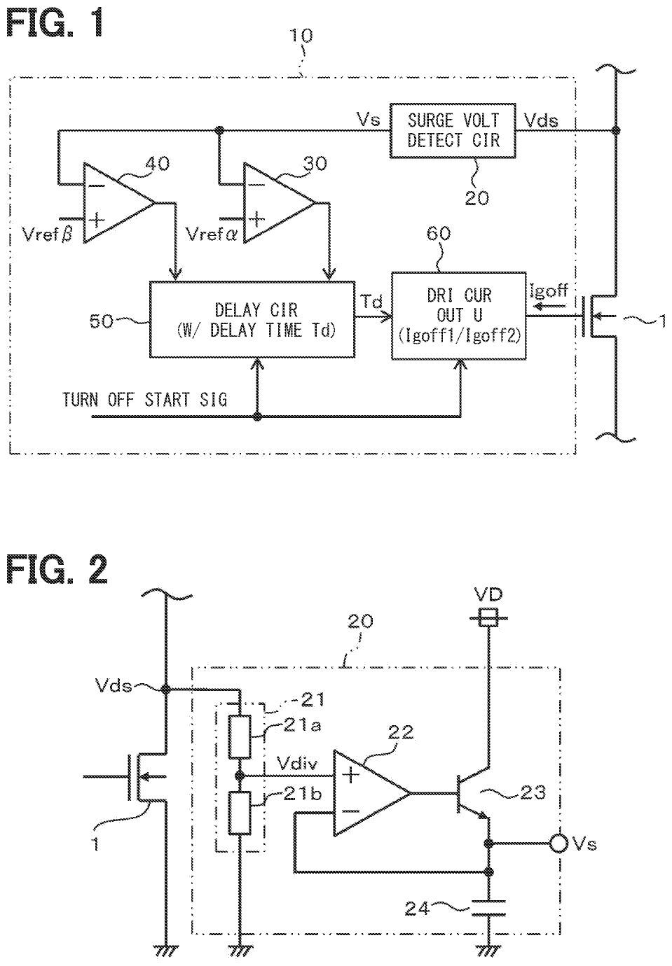

The description below explains a first embodiment of the present disclosure with reference to FIGS. 1 through 14.

FIG. 1 shows the overall electrical configuration. For example, an n-channel type MOS transistor 1 as a gate-driven switching element as a control target is provided in an energization path from a power supply terminal to a load. A gate voltage is applied to the gate by the gate drive device 10 to perform on and off switching drive control.

The gate drive device 10 includes a surge voltage detection circuit 20, a first comparator 30, a second comparator 40, a delay circuit 50 and a drive current output unit 60. In this embodiment, the gate drive device 10 performs a control operation for controlling the operation at the time of turn-off. When the turn off start signal is input from an external system as a drive signal for the MOS transistor 1, the off operation control is executed to the MOS transistor 1 as described later. In the actual gate drive device 10, when a turn-on start signal is supplied from the external system, the MOS transistor 1 is turned on by a turn-on drive circuit (not shown).

The surge voltage detection circuit 20 detects the drain-source voltage Vds of the MOS transistor 1 and detects the surge voltage Vs by a circuit that holds the peak value. The first comparator 30 determines the level of the surge voltage Vs detected by the surge voltage detection circuit 20, and detects whether or not it exceeds the determination level Vref_α. The second comparator 40 detects whether the level of the surge voltage Vs is less than the determination level Vref_β.

Note that the determination levels Vref_α and Vref_β described above are set so as to satisfy the relationship of the following equation (1) with respect to the withstand voltage Vref, which is the allowable upper limit value of the surge voltage Vs. Also, the lower limit value Vref_α and the upper limit value Vref_β of the determination level indicate the range of appropriate allowable values for the surge voltage Vs, as shown in the following equation (2).

Vref_α<Vref_β<Vref (1)

Vref_α<Vs<Vref_β (2)

The range of appropriate allowable values for the surge voltage Vs shown by the above equation (2) is set as the “target value” of the surge voltage, and it is possible to ensure the stability of the actual control operation by setting the range having a predetermined width. In addition, a margin is set so that the proper allowable value range of the surge voltage Vs is slightly lower than the withstand voltage Vref. Thus, as will be described later, it is configured to be able to cope with power supply fluctuations.

The delay circuit 50 inputs the determination results of the first comparator 30 and the second comparator 40, and based on these determination results, changes and sets the delay time Td and outputs it to the drive current output unit 60 as a timing signal. The delay time Td sets the switching timing of the gate drive current Igoff by the drive current output unit 60.

The drive current output unit 60 is configured to switch the gate drive current Igoff at turn-off to the gate of the MOS transistor 1 in two stages of a first gate drive current Igoff1 and a second gate drive current Igoff2.

When a turn-off start signal is supplied from the outside, the drive current output unit 60 first sets the gate drive current Igoff to the first gate drive current Igoff1 to turn off the MOS transistor 1 and starts the turn-off drive operation. After that, when the delay time Td elapses and the timing signal is given from the delay circuit 50, the driving current output unit 60 switches the gate drive current Igoff to the second gate drive current Igoff2 of which the current level is lower than the first gate driving current Igoff1, and continues the turn-off drive operation.

FIG. 2 shows the electrical configuration of the surge voltage detection circuit 20, which includes a voltage division circuit 21, an operational amplifier 22, an NPN type transistor 23 and a capacitor 24. The voltage division circuit 21 is a circuit in which two voltage division resistors 21a and 21b are connected in series. The circuit 21 is connected between the drain and the source of the MOS transistor 1, and outputs the surge voltage Vs generated at the turn off operation of the MOS transistor 1, as a division output voltage Vdiv.

The operational amplifier 22 has a non-inversion input terminal to which the division output voltage Vdiv of the voltage division circuit 21 is input, and an output terminal connected to the base of the transistor 23. The transistor 23 has a collector connected to the DC power supply VD and an emitter connected to the ground via the capacitor 24. The inversion input terminal of operational amplifier 22 is connected to the emitter of transistor 23.

With the above configuration, the surge voltage detection circuit 20 monitors the division voltage Vdiv obtained by dividing the drain-source voltage Vds of the MOS transistor 1 by the voltage division circuit 21 using the operational amplifier 22. When it becomes higher than the terminal voltage of the capacitor 24, the transistor 23 is turned on. The capacitor 24 is charged until the terminal voltage becomes equal to the division voltage Vdiv.

As a result, when the drain-source voltage Vds of the MOS transistor 1 drops through the surge voltage Vs, the terminal voltage of the capacitor 24 is charged to a voltage corresponding to the surge voltage Vs. Thus, a surge voltage Vs can be detected as the terminal voltage of the capacitor 24.

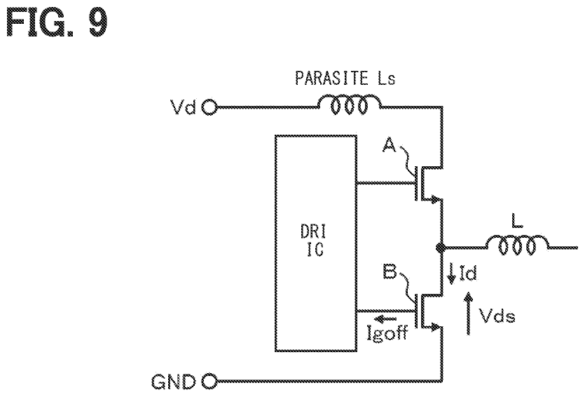

Next, prior to explaining the operation of the above configuration, with reference to FIGS. 9 to 14, the AGC technology will be schematically explained, and the background to the present disclosure from the technical difficulties in the AGC technology will be described.

First, as shown in FIG. 9, in a load power supply circuit in which two MOS transistors A and B are connected in series, for example, as a gate-driven semiconductor switching element, a configuration for executing the drive control of turning on and off using a drive IC is described as an object. A series circuit of the MOS transistors A and B is connected between a direct current power supply Vd and a ground GND, and a common connection point between the MOS transistors A and B is connected to an inductive load L.

The drive IC keeps the MOS transistor B in an off state, turns on the MOS transistor A, thereby supplying power to the inductive load L from the DC power supply Vd, turns off the MOS transistor A, and then turns on the MOS transistor B. As a result, a current flows from the inductive load L to the ground GND side.

At this time, when the MOS transistors A and B are driven to turn off, a surge voltage generated by the parasitic inductance Ls intervening in the energizing system and the inductance of the inductive load L is applied between the drain and the source of the MOS transistors A and B. If a surge voltage Vs exceeding the withstand voltage is applied to a MOS transistor, it may be damaged or destroyed, so it must be suppressed. The surge voltage increases as the turn-off time becomes shorter.

On the other hand, in a MOS transistor, when the drain current flowing in the turn-on state decreases during the turn-off driving operation, a turn-off loss Ltoff corresponding to the integrated value of the product with the drain-source voltage Vds is generated. In other words, the longer the turn-off time, the larger the turn-off loss Ltoff caused by the current flowing in a state where the voltage is applied to the MOS transistor.

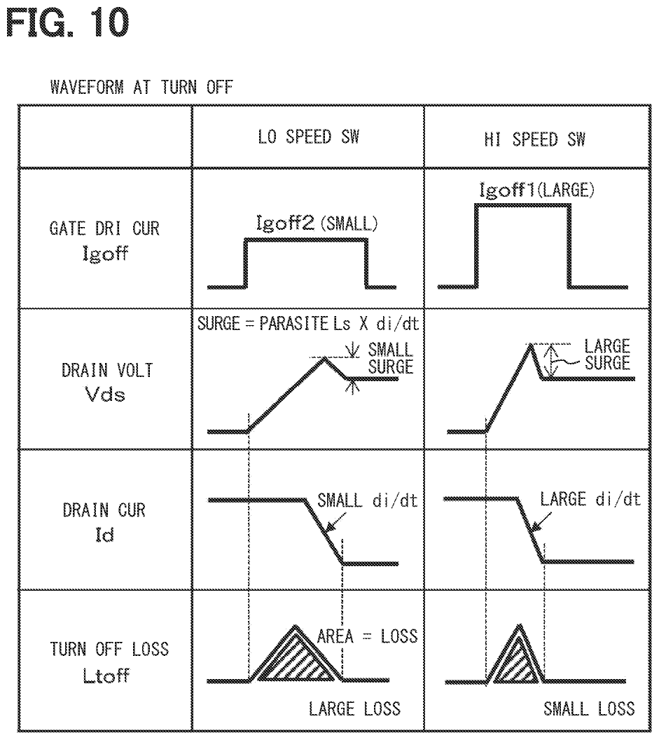

The drive IC is required to suppress the turn-off loss Ltoff while suppressing the surge voltage Vs described above. In this case, as shown in FIG. 10, when the drive IC turns off the MOS transistor B, for example, if the gate drive current Igoff is supplied, the drain current Id decreases while the drain voltage Vds rises, so that the product of these values, that is, the portion corresponding to the area is defined as the turn-off loss Ltoff.

At this time, in the low speed switching operation, since the gate drive current Igoff is small, the change in the drain current Id is small and the turn-off time is long. As a result, the surge voltage Vs can be kept small, but the turn-off loss Ltoff increases. Further, in high-speed switching operation, since the gate drive current Igoff is large, the change in the drain current Id is large and the turn-off time is shortened. As a result, the surge voltage Vs increases, but the turn-off loss Ltoff can be reduced.

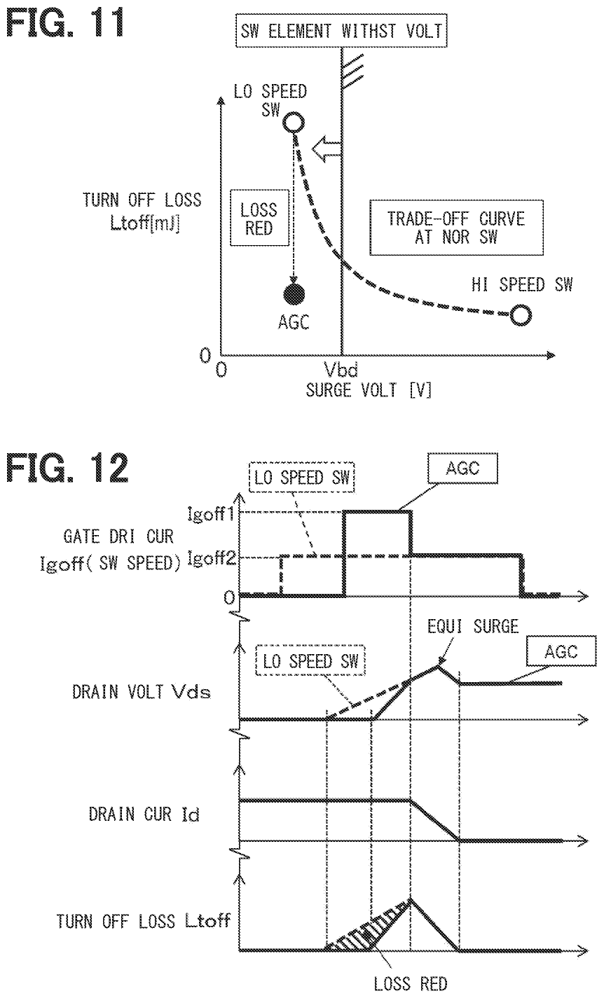

As for the turn-off drive of the MOS transistor, suppression of the surge voltage Vs and suppression of the turn-off loss Ltoff as described above have a trade-off relationship when setting the level of the gate drive current Igoff. For example, as shown in FIG. 11, the relationship between the surge voltage Vs and the turn-off loss Ltoff when the gate drive current Igoff is used as a parameter is a characteristic curve connecting the points indicated by white circles with a dashed line.

Therefore, when the gate drive current Igoff is fixed and the turn-off drive is performed, it is common to set the gate drive current Igoff to reduce the turn-off loss Ltoff as low as possible within a range satisfying the condition that the surge voltage Vs is equal to or lower than the withstand voltage Vref, according to the condition indicated by the dashed line in FIG. 11.

On the other hand, the AGC technology on which the present disclosure is applied realizes the turn-off drive that can substantially reduce the turn-off loss Ltoff that may be large in the low-speed switching region in FIG. 11.

Specifically, as shown in FIG. 12, the first gate drive current Igoff1, which is large and has a condition for executing the high-speed switching, is set at the start of turn-off driving, and it is switched and set to the second gate drive current Igoff2, which is small and has a condition for executing the low-speed switching, before the surge voltage Vs becomes high.

As a result, as shown in FIG. 12, the slope of the drain voltage Vds increases during the period of the first gate drive current Igoff1, and the drain voltage Vds rises in a shorter time than when the gate drive current is small. Therefore, the turn-off loss Ltoff is reduced. Further, when switching to the second gate drive current Igoff2, the slope of the drain voltage Vds decreases, so the surge voltage Vs can be suppressed.

In this case, in the AGC control, which is a prerequisite, a condition for operating on the safe side in consideration of the characteristic variation of the target switching element. Thus, the switching timing for switching from the first gate drive current Igoff1 to the second gate drive current Igoff2 may deviate from the optimum condition, so that it may be difficult to optimally set the reduction of the turn-off loss Ltoff. Moreover, in a configuration in which the surge voltage is not monitored, it is unknown whether the surge voltage is within the withstand voltage range.

Therefore, in the present embodiment, instead of setting the switching timing from the first gate driving current Igoff1 to the second gate driving current Igoff2 in advance, a configuration is adopted in which the optimal conditions are set according to the characteristics of the MOS transistor 1 as the target switching element. Moreover, since the surge voltage Vs of the MOS transistor 1 is monitored to set the switching timing, it is possible to reliably drive under the condition of the surge voltage Vs lower than the withstand voltage Vref. Further, by always automatically setting such switching timing, even if the operating conditions fluctuate, it is possible to cope with such fluctuations.

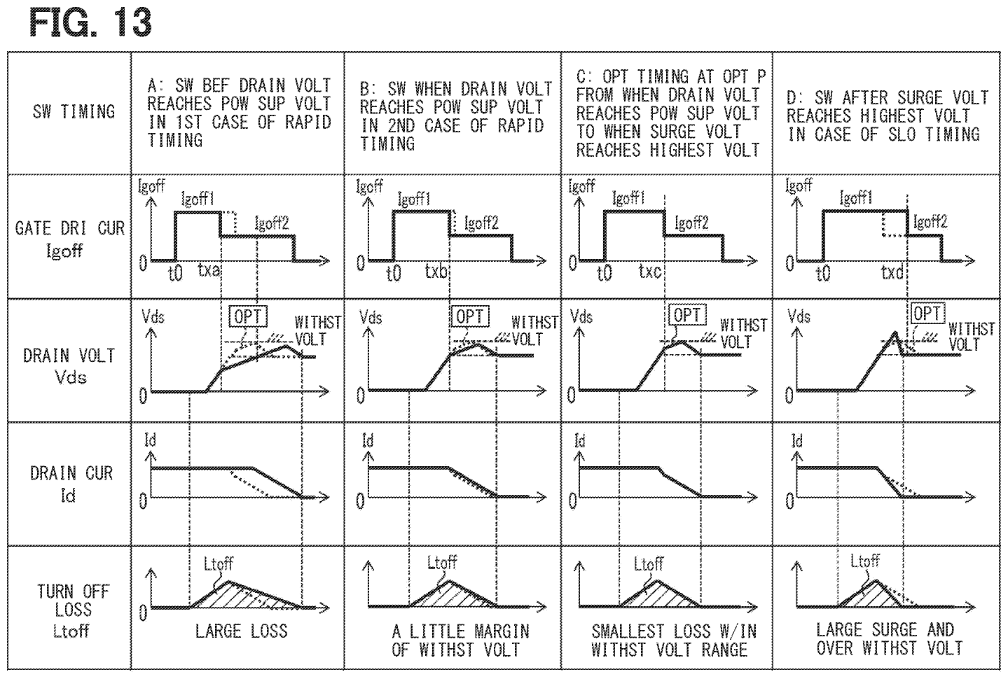

FIG. 13 shows four patterns of optimal switching timing from the first gate driving current Igoff1 to the second gate driving current Igoff2 and the relationship between the drain voltage Vds and the drain current Id and the turn-off loss Ltoff before and after that switching timing. The gate driving current Igoff is set to the first gate driving current Igoff1 at time t0, and is switched to the second gate driving current Igoff2 at the switching timing time tx.

First, when the switching timing of A is early In pattern 1, since switching is performed at time txa before the drain voltage Vds reaches the power supply voltage, the drain current Id flows even after time tx, and the turn-off loss Ltoff is increased. On the other hand, the surge voltage Vs is suppressed to a low level, and there is still some margin for the withstand voltage.

Next, when the switching timing of B is early In pattern 2, switching is performed at time txb when the drain voltage Vds reaches the power supply voltage, so the turn-off loss Ltoff is relatively close to the optimal state. Also, the surge voltage Vs is approaching the withstand voltage, but there is still some margin.

In the optimum timing pattern of C, the drain voltage Vds is switched at the timing of time txc when the drain voltage Vds is disposed between the power supply voltage and the withstand voltage, the turn-off loss Ltoff is minimized, and the withstand voltage is also optimum.

In the pattern in which the switching timing of D is late, the drain voltage Vds is switched at the timing of time txd after the drain voltage Vds passes through the surge voltage Vs. Thus, it becomes a state that the surge voltage is high and exceeds the withstand voltage.

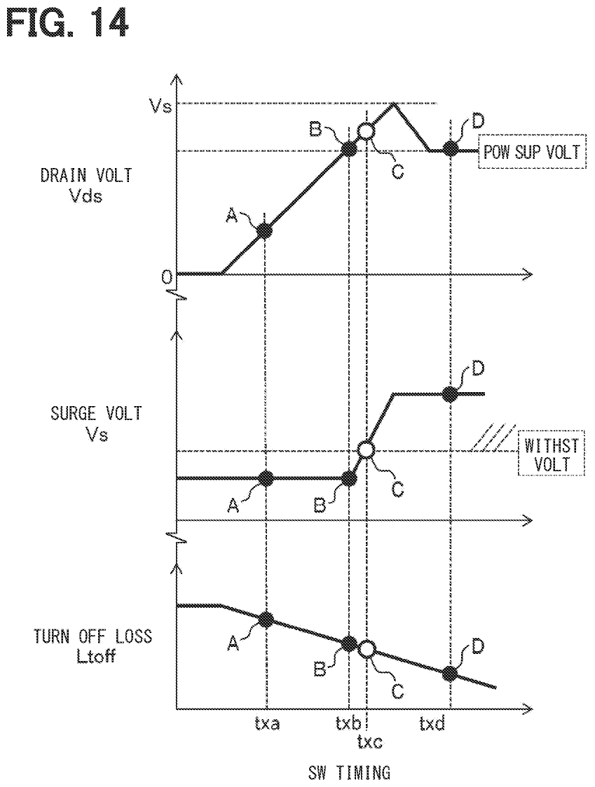

The results are summarized as shown in FIG. 14. That is, during the period from when the drain voltage Vds of the MOS transistor 1 starts turning off until it reaches the power supply voltage after turning off, it shows a feature that the magnitudes of the surge voltage Vs and the turn-off loss Ltoff change according to the timing of switching from the first gate driving current Igoff1 to the second gate driving current Igoff2.

As described above, the optimum switching timing is the time txc of pattern C, the surge voltage Vs satisfies to be equal to or lower than the withstand voltage, and the turn-off loss Ltoff is also a relatively low value. In the cases of A and B, which are switched at a timing earlier than the time txc, the surge voltage Vs satisfies to be equal to or lower than the withstand voltage, but the turn-off loss Ltoff is large. Then, in the case of D, which is switched at a timing later than the time txc, the turn-off loss Ltoff is small, but the surge voltage Vs exceeds the withstand voltage.

From this result, it can be seen that the surge voltage detection circuit 20 is controlled to set the timing txc at which the drain voltage Vds corresponding to the C pattern is detected as the switching timing.

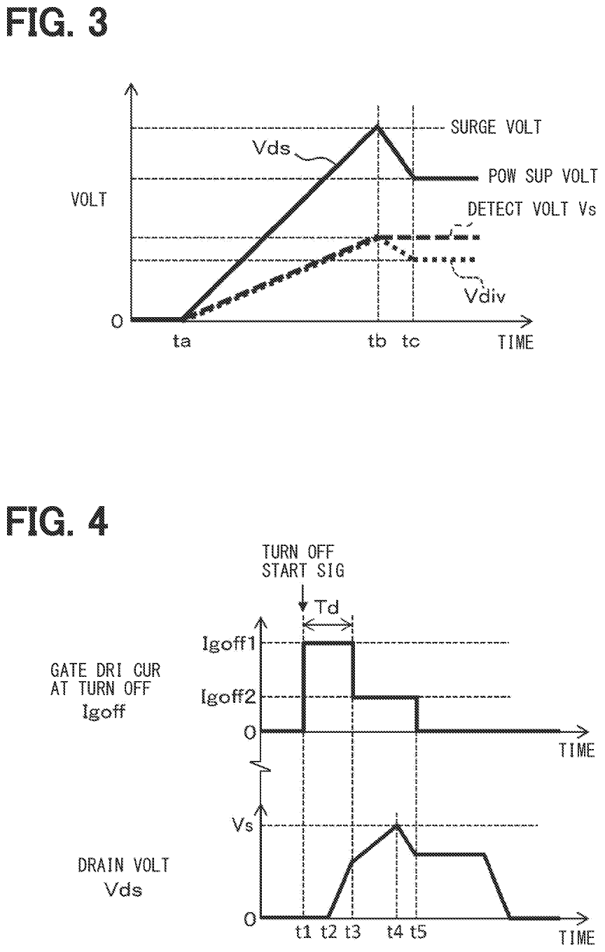

Next, specific control contents in this embodiment will be described with reference to FIGS. 3 to 8.

First, the operation of the surge voltage detection circuit 20 will be described with reference to FIG. 3. In this configuration, the MOS transistor 1 has its drain connected to the power supply through the load and its source connected to the ground. The drain voltage Vds of the MOS transistor 1 is substantially at the ground level when it is in an on state.

When the MOS transistor 1 is turned off by the turn-off signal, the potential of the gate drops, and at time to when the gate voltage reaches near the threshold voltage, the MOS transistor 1 starts to shift to the off state, and the drain voltage Vds starts to rise. The drain voltage Vds increases as the on state of the MOS transistor 1 proceeds, exceeds the power supply voltage under the influence of the type of load and parasitic inductance, and reaches the surge voltage Vs at time tb. After that, the drain voltage Vds drops and reaches the power supply voltage at time tc.

In the surge voltage detection circuit 20, the drain voltage Vds is monitored by the voltage division circuit 21 at this time, and the division voltage Vdiv is input to the operational amplifier 22. In the initial state, the terminal voltage of the capacitor 24, that is, the detection voltage Vs of the surge voltage is 0 V, so the operational amplifier 22 drives the transistor 23 to charge the capacitor 24.

The operational amplifier 22 charges the capacitor 24 until the division voltage Vdiv reaches a voltage corresponding to the surge voltage Vs. When the drain voltage Vds of the MOS transistor 1 starts to drop after time tb, the division voltage Vdiv also drops, so the operational amplifier 22 stops driving the transistor 23 and the detection voltage Vs of the surge voltage is maintained. As a result, the surge voltage detection circuit 20 can detect the surge voltage Vs when the drain voltage Vds of the MOS transistor 1 reaches its peak value.

Next, adjustment control of the delay time Td by the gate drive device 10 will be described with reference to FIGS. 4 to 8. FIG. 4 shows the temporal transition of the gate drive current supplied to the gate of the MOS transistor 1 by the gate drive device 10 and the temporal transition of the drain voltage Vds of the MOS transistor 1 at this time.

As shown in the drawing, when the turn-off start signal is applied, the gate drive device 10 causes the MOS transistor 1 in the on state to flow the current from the gate of the MOS transistor 1 at time t1 with the first gate drive current Igoff1. As the gate voltage of MOS transistor 1 decreases, the drain voltage Vds begins to rise at time t2. After that, the gate drive device 10 switches from the first gate driving current Igoff1 to the second gate driving current Igoff2 at time t3 when the delay time Td has elapsed from time t1.

The drain voltage Vds of the MOS transistor 1 rises with a slightly gentle change, exceeds the power supply voltage, and reaches the peak voltage, i.e., the surge voltage Vs at time t4. Thereafter, the drain voltage Vds of the MOS transistor 1 begins to drop, and settles down to the power supply voltage at time t5.

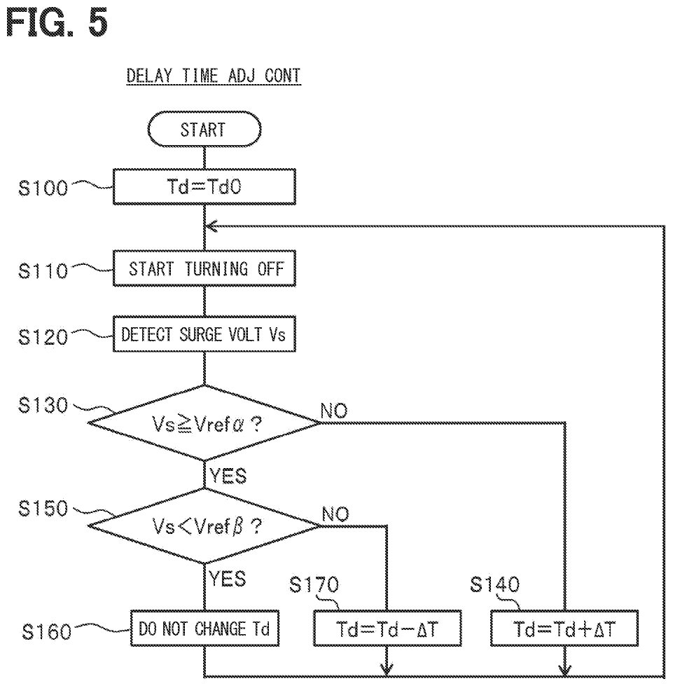

FIG. 5 shows the flow of adjustment control of the delay time Td by the gate drive device 10. The operation of each part in the gate drive device 10 will be described below according to the flow of FIG. 5. When a turn-off start signal is input from the outside to the MOS transistor 1 that is controlled to be turned on, the gate drive device 10 always performs the following turn-off drive control.

First, the gate drive device 10 sets Td0 as the initial value of the delay time Td in step S100. The delay time Td is the value of the signal that the delay circuit 50 sets to the drive current output unit 60, and the drive current output unit 60 has the timing of switching the gate drive current Igoff from the first gate drive current Igoff1 to the second gate drive current Ioff2 when the timing signal is given after the delay time Td has passed.

In this case, the initial value Td0 of the delay time Td is set to a value within a range in which the surge voltage Vs does not exceed the withstand voltage, taking into consideration of variations in characteristics of MOS transistor 1. That is, the initial value Td0 is set to a value that is disposed on the safe side where the MOS transistor 1 is not destroyed, but the turn-off loss Ltoff is increased.

Next, the gate drive device 10 starts turn-off drive of the MOS transistor 1 by the drive current output unit 60 in step S110. Here, the drive current output unit 60 operates to discharge the gate of the MOS transistor 1 with the first gate drive current Igoff1. When the timing signal is given after the delay time Td has elapsed, the driving current output unit 60 switches to the second gate driving current Igoff2 to discharge the gate of the MOS transistor 1.

As a result, at time t1, the MOS transistor 1, which had been in the turn on state, starts to be turned off with the first gate drive current Igoff1. When the gate voltage drops and reaches the threshold voltage, the drain voltage Vds starts to rise. At time t3 while the drain voltage Vds is increasing, the gate drive current Igoff is switched to the second gate drive current Igoff2, which is smaller than the first gate drive current Igoff1. As a result, the rising slope of the drain voltage Vds becomes smaller than that of the first gate drive current Igoff1.

Thereafter, the drain voltage Vds rises above the power supply voltage, reaches the surge voltage Vs at time t4, and then returns to the power supply voltage at time t5. As a result, at time t5, the MOS transistor 1 is turned off and the gate charge is also discharged, so that the second gate driving current Igoff2 becomes zero.

Next, in step S120, the surge voltage detection circuit 20 holds the drain voltage Vds of the MOS transistor 1 reaching the peak value, i.e., the surge voltage Vs at time t4, and sets the drain voltage Vds as the surge voltage Vs to input it to the first comparator 30 and the second comparator 40 .

It is determined by the first comparator 30 and the second comparator 40 whether or not the surge voltage Vs is within the proper allowable range indicated by the above-described equation (2). First, in step S130, the first comparator 30 determines whether or not the level of the surge voltage Vs input from the surge voltage detection circuit 20 is equal to or higher than the determination level Vref_α.

In this case, as described above, since the initial value Td0 of the delay time Td is set short, it is assumed that the surge voltage Vs is also small and does not reach the proper allowable range. Accordingly, in step S130, the determination is initially “NO”, and the process proceeds to step S140 to set the delay time Td longer than the previous delay time Td by a predetermined time ΔT.

Lengthening the delay time Td means lengthening the period during which the high-level first gate driving current Igoff1 flows as the gate driving current Igoff, thereby increasing the surge voltage Vs. The value of the predetermined time ΔT is set to an appropriate time so that the increased surge voltage Vs at this time does not exceed the appropriate allowable value range described above.

Thereafter, the MOS transistor 1 is turned on again, and when the next turn-off start signal is given, the gate drive device 10 returns to step S110, and the drive current output unit 60 starts to turn off the MOS transistor 1. At this time, the drive current output unit 60 starts discharging the gate charge of the MOS transistor 1 with the first gate drive current Igoff1, and when the newly set delay time Td elapses and the timing signal is applied, the unit 6 switched to the second gate drive current Igoff2.

As a result, at time t1, the MOS transistor 1, which had been in the turn on state, starts to be turned off with the first gate drive current Igoff1. When the gate voltage drops and reaches the threshold voltage, the drain voltage Vds starts to rise. At time t3 while the drain voltage Vds is increasing, the gate drive current Igoff is switched to the second gate drive current Igoff2, which is smaller than the first gate drive current Igoff1. As a result, the rising slope of the drain voltage Vds becomes smaller than that of the first gate drive current Igoff1.

Thereafter, the drain voltage Vds rises above the power supply voltage, reaches the surge voltage Vs at time t4, and then returns to the power supply voltage at time t5. As a result, at time t5, the MOS transistor 1 is turned off and the gate charge is also discharged, so that the second gate driving current Igoff2 becomes zero.

Next, in step S120, the surge voltage detection circuit 20 holds the drain voltage Vds of the MOS transistor 1 reaching the peak value, i.e., the surge voltage Vs at time t4, and sets the drain voltage Vds as the surge voltage Vs to input it to the first comparator 30 and the second comparator 40 . At this time, since the period of the first gate drive current Igoff1 is longer, the surge voltage Vs becomes a higher value than the previous time.

For example, when the surge voltage Vs reaches the voltage between the determination levels Vref_α and Vref_β, that is, the proper allowable value range, the first comparator 30 determines “YES” in step S130 and the process proceeds to step S150. Furthermore, in step S150, the second comparator 40 determines “YES” because the surge voltage Vs is smaller than the determination level Vref_β, and the process proceeds to step S160. In step S160, nothing is actually performed, but the process returns to step S110 while maintaining the previously set delay time Td without changing the delay time Td.

If the surge voltage Vs still does not fall within the appropriate allowable range and the result of step S130 is “NO”, the delay time Td is still short, so the predetermined time ΔT is added to the delay time Td again in step S140. Subsequently, steps S110 to S130 are executed in the same manner, and the delay time Td is changed and set until the surge voltage Vs at turn-off falls within the appropriate allowable range.

In this manner, when the surge voltage Vs falls within the proper allowable range, that is, the determination level Vref_α or more and less than the determination level Vref_β, the determination of “YES” is obtained in steps S130 and S150, and the delay time Td set at this time is set to be an appropriate value. Thus, in step S160, this delay time Td is held without being changed.

On the other hand, even with the delay time Td set as described above, the value of the surge voltage Vs may deviate from the proper allowable range due to some variable factor. For example, when the surge voltage Vs becomes smaller than the determination level Vref_α, “NO” is determined in step S130, and in step S140, the delay time Td is reset to a value obtained by adding a predetermined time ΔT.

Further, when the surge voltage Vs exceeds the determination level Vref_β, “NO” is determined in step S150, and in step S170, the delay time Td is reset to a value obtained by subtracting a predetermined time ΔT.

In this way, even if the surge voltage Vs fluctuates and falls outside the range of the proper allowable value, the delay time Td is adjusted and reset each time, so that it is controlled to fall within the range of the proper allowable value again.

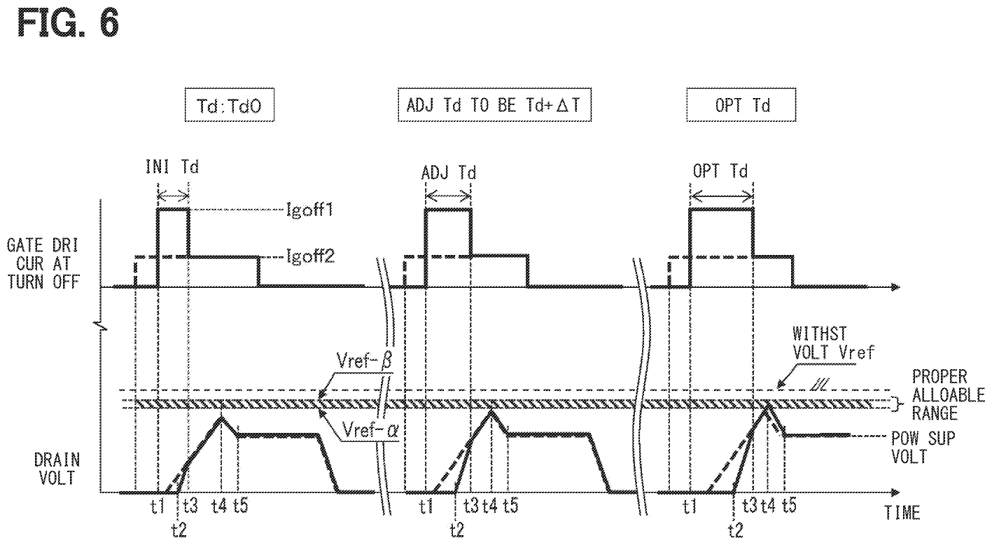

Next, as shown in FIG. 6, the adjustment process of the delay time Td described above is carried out so as to reach an appropriate value through three states. In the state where the delay time Td is set to the initial value Td0, as shown on the left side in FIG. 6, when the energization starts at time t1 using the first gate drive current Igoff1 at the turn off operation, the gate voltage approaches the threshold voltage, and the drain voltage Vds begins to rise at time t2. At this time, the slope of the increase in the drain voltage Vds is large.

After that, at time t3 when the delay time Td set to the initial value Td0 has elapsed, the gate drive current is switched to the second gate drive current Igoff2, and the slope of the increase in the drain voltage Vds becomes smaller. The drain voltage Vds rises above the power supply voltage, reaches the surge voltage Vs at time t4, and then falls. The drain voltage Vds becomes equal to the power supply voltage at time t5. Since the MOS transistor 1 is turned off, the gate drive current Igoff becomes zero.

Since the delay time Td0 immediately after the start of control is set to be short, the surge voltage Vs is a low value that is within the appropriate allowable range, that is, does not reach the reference value Vref_α. Therefore, the margin for the withstand voltage is large and does not exceed the withstand voltage, but the period in which the drain voltage Vds rises is long, so the turn-off loss Ltoff is large.

Therefore, the delay time Td is adjusted by the delay circuit 50 and added by a predetermined time AT. When the delay time Td is adjusted, as shown in the center of FIG. 6, the time interval from time t2 to time t3 is lengthened, the period in which the drain voltage Vds has a large rising slope is lengthened, and the surge voltage Vs becomes larger.

In this way, when the delay time Td is adjusted by the delay circuit 50 and set to an optimum value, the surge voltage Vs falls within the appropriate allowable range, that is, between the determination values Vref_α and Vref_β, as shown on the right side of FIG. 6. As a result, it is possible to set the delay time Td that suppresses the turn-off loss Ltoff within a range in which the surge voltage Vs does not exceed the withstand voltage Vref.

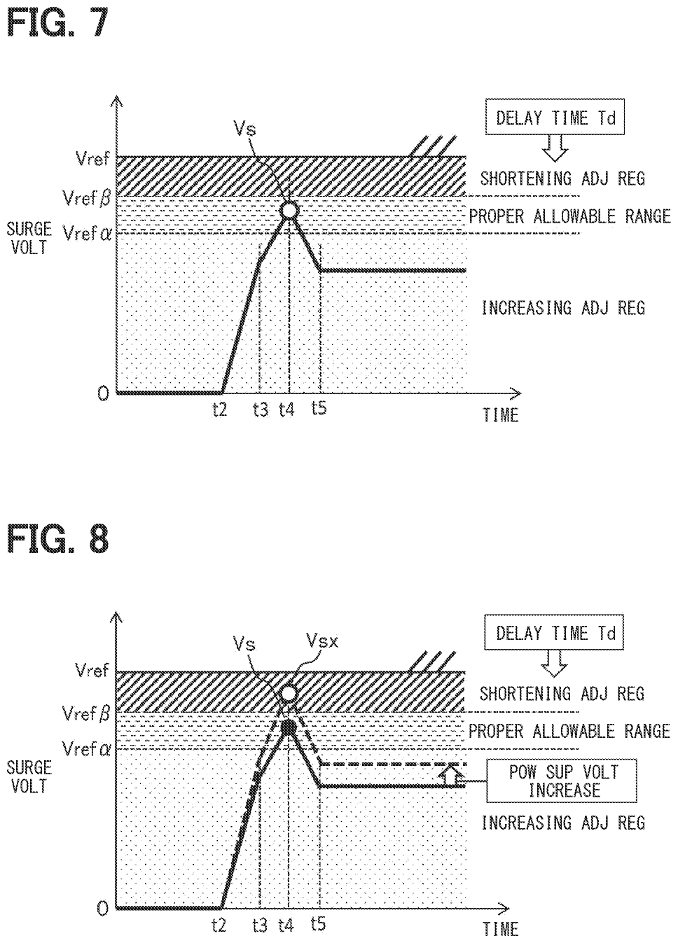

In the state where the delay time Td is set to the optimum value in this way, the surge voltage Vs is adjusted so as to fall within the proper allowable range, as shown in FIG. 7. In the drawing, when the surge voltage Vs falls below the range of the proper allowable value, the delay time Td is adjusted so that it is increased. When the surge voltage Vs is disposed in a region over the range of the proper allowable value, the delay time Td is adjusted so that it is shortened.

As described above, even if the delay time Td is adjusted and set to an optimum value, if an environmental change such as an increase in the power supply voltage occurs, the surge voltage Vs may change to be a large surge voltage Vsx exceeding the range of the appropriate allowable value as shown in FIG. 8. In preparation for such a case, the proper allowable value range of the surge voltage Vs is set with a certain margin with respect to the withstand voltage Vref. As a result, the surge voltage Vsx enters the region of shortening adjustment, so the delay time Td is readjusted to be shorter according to the flow of FIG. 5 described above.

According to the first embodiment as described above, a configuration is obtained such that the surge voltage detection circuit 20, the comparators 30 and 40, and a delay circuit 50 are provided to set the switching timing, for switching the MOS transistor 1 from the high first gate drive current Igoff1 to the low second gate drive current Igoff2 using the drive current output unit 60, as the delay time Td.

As a result, the delay time Td can be set so that the level of the surge voltage Vs detected by the surge voltage detection circuit 20 falls within an appropriate allowable range set slightly lower than the withstand voltage Vref. It is possible to always drive with an appropriate delay time Td in response to variations in the characteristics of the MOS transistor 1 and changes in the characteristics thereof over time. As a result, the turn-off driving operation can be performed with the lowest turn-off loss Ltoff within a range not exceeding the withstand voltage Vref.

Further, as described above, the delay time Td is adjusted so that the level of the surge voltage Vs falls within the proper allowable range set with a margin with respect to the withstand voltage Vref. Thus, it is possible to suppress the surge voltage Vs from exceeding the withstand voltage Vref in response to the variations of the power supply voltage.

### Second Embodiment

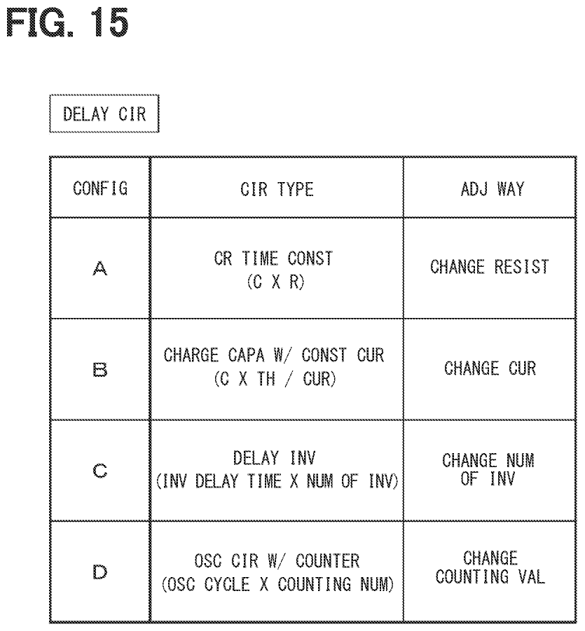

FIGS. 15 to 19 show the second embodiment, and show the specific configuration of the delay circuit 50 used in the first embodiment. FIG. 15 shows configuration types of the delay circuit 50 in four types A to D. As a function of the delay circuit 50, it is necessary to achieve a function of changing and setting the delay time Td.

The A type configuration is configured to be adjusted by the CR time constant as a circuit system, and is adjusted by changing the resistance value. The B type has a configuration in which a capacitor is charged with a constant current as a circuit system and a delay time is set until the threshold voltage is reached, and adjustment is performed by changing the value of the constant current.

In the C type, a delay time generated in an inverter circuit is used as a circuit system, and a plurality of inverter circuits are provided in series, and the delay time is adjusted by changing the number of inverter circuits. The D type has a configuration in which an oscillator circuit and a counter are provided as a circuit system, and the delay time is adjusted by changing the count value.

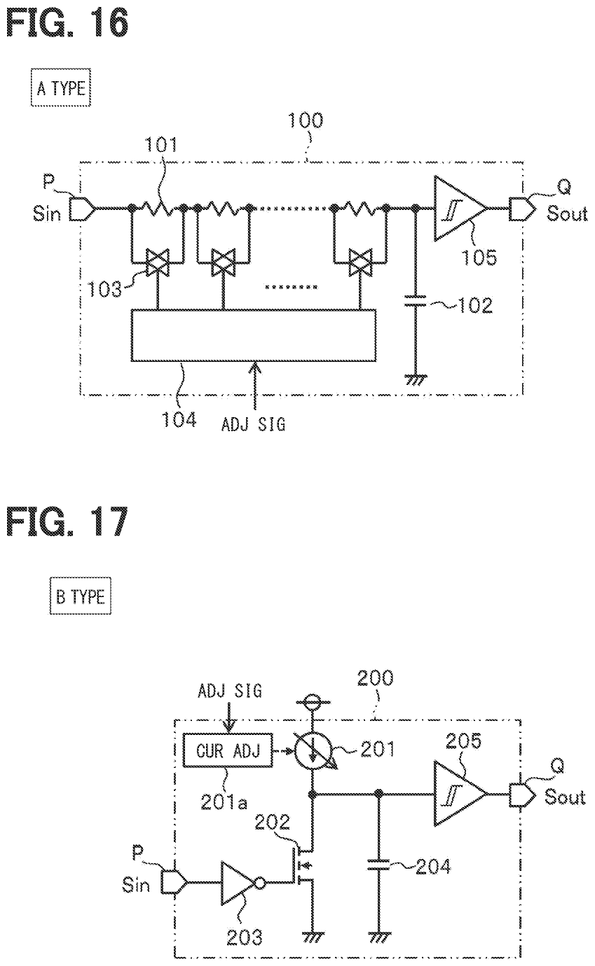

An example of a specific example is shown below. FIG. 16 shows an A-type delay circuit 100. In this configuration, the input signal Sin to the terminal P is output as the output signal Sout from the terminal Q when the delay time Td has passed. The input signal Sin corresponds to a turn-off start signal, and the output signal Sout is a switching timing signal for the delay time Td. Further, the adjustment signal is input as a signal corresponding to whether the delay time Td is to be lengthened or shortened based on the detection results of the comparators 30 and 40.

A CR time constant circuit including a plurality of series-connected resistors 101 and capacitors 102 is provided, and both terminals of each resistor 101 are connected to an analog switch 103 for short-circuiting. The plurality of analog switches 103 are controlled to be turned on and off by the adjustment circuit 104. The buffer circuit 105 outputs a high-level signal to the terminal Q when the terminal voltage of the capacitor 102 reaches the threshold voltage.

In the above configuration, the adjustment circuit 104 initially turns on a predetermined number of analog switches 103 to set a short CR time constant. Thereby, the delay time Td corresponding to the delay time Td0 is set. When the adjustment signal is input to change the delay time Td, the adjustment circuit 104 turns off the on-state analog switch 103 to enable the resistor 101 and lengthen or shorten the CR time constant. Thereby, the delay time Td can be changed and set by the predetermined time ΔT.

FIG. 17 shows a B-type delay circuit 200. A constant current circuit 201 capable of adjusting the current value and a MOS transistor 202 are connected in series and connected between the power supply and the ground. The constant current value of the constant current circuit 201 is changed and set by the current adjustment circuit 201a. The current adjustment circuit 201a changes and sets the current value according to the adjustment signal.

The gate of MOS transistor 202 is supplied with a signal obtained by inverting an input signal Sin to terminal P by the inverter circuit 203. A capacitor 204 is charged by the constant current circuit 201. The buffer circuit 205 outputs a high-level signal to the terminal Q when the terminal voltage of the capacitor 204 reaches the threshold voltage.

When a high level input signal Sin is input, the MOS transistor 202 changes from the on state to the off state. The capacitor 204 starts to be charged with the constant current set by the constant current circuit 201 from the discharged state. A high-level signal Sout is output to the terminal Q when the charging of the capacitor 204 progresses and the terminal voltage reaches the threshold voltage after the delay time has elapsed.

In the above configuration, the current adjustment circuit 201a is set so that the constant current value of the constant current circuit 201 is initially set to a large value and the terminal voltage of the capacitor 204 rises quickly. Thereby, the delay time Td corresponding to the delay time Td0 is set. When the adjustment signal is input to change the delay time Td, the current adjustment circuit 201a lengthens or shortens the charging time of the capacitor 204 by changing the constant current value by a predetermined value. Thereby, the delay time Td can be changed and set by the predetermined time ΔT.

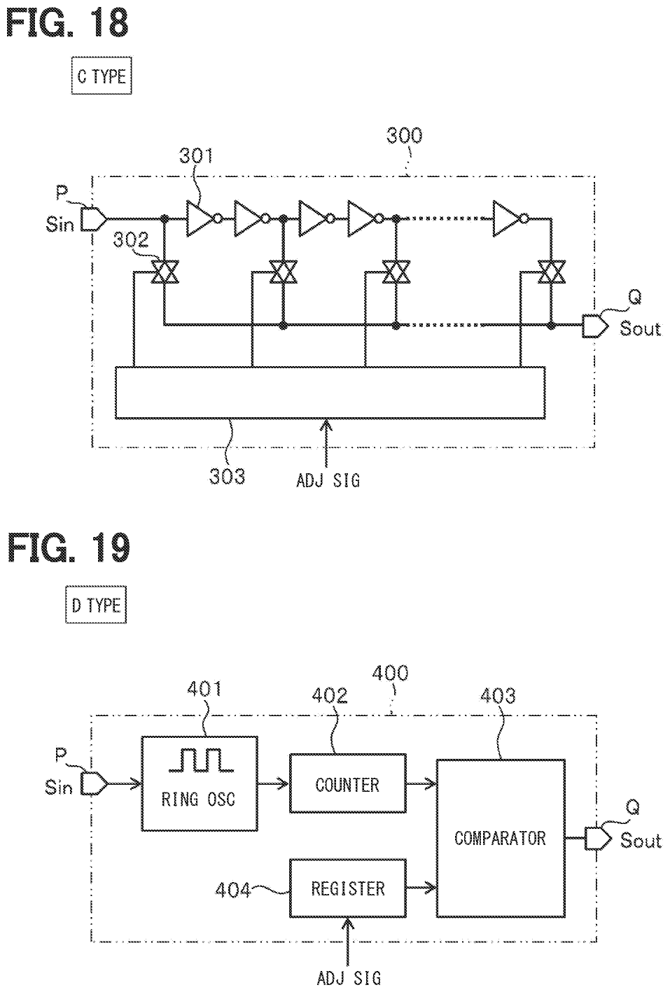

FIG. 18 shows a C-type delay circuit 300. In the delay circuit 300, a plurality of sets of two inverters 301 for creating a delay time are connected in series. A plurality of inverters 301 connected in series have the input terminal of the first stage connected to the terminal P, and the output terminal of the last stage connected to the terminal Q via the analog switch 302. Another analog switch 302 is connected between the terminal Q and the terminal P, and different analog switches 302 are also connected between the connection points of two inverters 301, respectively. The plurality of analog switches 302 are controlled to be turned on and off by the adjustment circuit 303.

In the above configuration, the adjustment circuit 303 initially turns on the preset analog switch 302 to connect a predetermined number of inverters 301 between the terminals P and Q. As a result, the input signal Sin to the terminal P is output as the output signal Sout from the analog switch 302 in the ON state to the terminal Q via the predetermined number of inverters 301. At this time, the delay time Td corresponding to the delay time Td0 is set by the delay time corresponding to the number of inverters 301 passed through.

Further, when an adjustment signal is input to change and set the delay time Td, the adjustment circuit 302 turns off the analog switch 302 that is in the ON state and turns on the adjacent analog switch 302 so that the number of inverters 301 that pass through is changed to two. Thereby, the delay time Td can be changed and set by the predetermined time ΔT.

FIG. 19 shows a D-type delay circuit 400. In the delay circuit 400, the terminal P is connected to terminal Q via a ring oscillator 401, a counter 402 and a comparator 403. A register 404 is connected to the other input terminal of the comparator 403.

The ring oscillator 401 outputs a pulse signal with a predetermined frequency to the counter 402 when triggered by the input signal Sin of the terminal P. The comparator 403 outputs an output signal Sout to terminal Q when the level of the pulse count signal input from the counter 402 reaches the reference level set by the register 404. When the adjustment signal for setting the delay time is input, the register 404 outputs to the comparator 403 a reference level signal with the delay time changed.

In the above configuration, the register 404 initially outputs a preset reference level signal to the comparator 403. As a result, the time until the pulse signal reaches the reference level by the counter 402 is set as the delay time Td corresponding to the delay time Td0.

When the adjustment signal is input to change the delay time Td, the register 404 changes the reference level by a predetermined value to increase or decrease the counting number of the pulse signal counted by the counter 402. Thus, the delay time Td can be changed and set by a predetermined time ΔT.

As described above, in the delay circuit 50 of the first embodiment, the delay time can be set by using the various delay circuits 100 to 400 from the A type to the D type.

In addition to the delay circuits described above, general delay circuits may be employed.

### Other Embodiments

The present disclosure should not be limited to the embodiments described above. Various embodiments may further be implemented without departing from the scope of the present disclosure, and may be modified or expanded as described below.

In the above embodiment, the adjustment control of the delay time Td is always performed during the drive control of the MOS transistor 1, alternatively, the adjustment control of the delay time Td may be performed when the apparatus is started, or may be performed periodically at a predetermined timing during operation of the apparatus.

In the above-described embodiment, the target value of the surge voltage Vs is set as the range of the appropriate allowable values shown by the formula (2). The setting range may be appropriately set in consideration with the controllability.

Further, in the above-described embodiment, the surge voltage detection circuit 20 is provided, alternatively, the surge voltage Vs may be detected by another detection configuration.

In the above embodiment, the MOS transistor 1 is used as a gate-driven switching element, alternatively, an insulated gate bipolar transistor (i.e., IGBT Insulated Gate Bipolar Transistor) may also be a control target.

The controllers and methods described in the present disclosure may be implemented by a special purpose computer created by configuring a memory and a processor programmed to execute one or more particular functions embodied in computer programs. Alternatively, the controllers and methods described in the present disclosure may be implemented by a special purpose computer created by configuring a processor provided by one or more special purpose hardware logic circuits. Alternatively, the controllers and methods described in the present disclosure may be implemented by one or more special purpose computers created by configuring a combination of a memory and a processor programmed to execute one or more particular functions and a processor provided by one or more hardware logic circuits. The computer programs may be stored, as instructions being executed by a computer, in a tangible non-transitory computer-readable medium.

It is noted that a flowchart or the processing of the flowchart in the present application includes sections (also referred to as steps), each of which is represented, for instance, as S901. Further, each section can be divided into several sub-sections while several sections can be combined into a single section. Furthermore, each of thus configured sections can be also referred to as a device, module, or means.

While the present disclosure has been described with reference to embodiments thereof, it is to be understood that the disclosure is not limited to the embodiments and constructions. The present disclosure covers various modification examples and equivalent arrangements. In addition, various combinations and configurations, as well as other combinations and configurations that include only one element, more, or less, are within the scope and spirit of the present disclosure.

What is claimed is:

1. A gate drive device that drives and controls a gate of a gate drive type switching element when driving the gate to turn on or off the switching element, the gate drive device comprising:
a surge voltage detection circuit for detecting, as a surge voltage, a peak voltage between a drain and a source or a voltage between a collector and an emitter of the switching element when the switching element is turned off;
a delay circuit for outputting a timing signal when a predetermined delay time elapses after a turn-off start signal is input; and
a driving current output unit for starting to supply a first gate drive current to the gate of the switching element when the turn-off start signal is input, and for starting to supply a second gate drive current lower than the first gate drive current to the gate of the switching element when the delay circuit outputs the timing signal, wherein:
the delay circuit is configured to change and set the delay time when the surge voltage detected by the surge voltage detection circuit is different from a target value.

2. The gate drive device according to claim 1, wherein:
the target value is set as a range of an appropriate allowable value defined by a lower limit value and an upper limit value of a determination level.

3. The gate drive device according to claim 1, wherein:
the target value is set to a value obtained by setting a predetermined margin with respect to a withstand voltage of the switching element.

4. The gate drive device according to claim 1, wherein:
the delay circuit sets the delay time longer by a predetermined time when the surge voltage detected by the surge voltage detection circuit is smaller than the target value; and the delay circuit sets the delay time shorter by a predetermined time when the surge voltage detected by the surge voltage detection circuit is larger than the target value.

5. The gate drive device according to claim 1, wherein:
the delay circuit includes a comparator that compares the surge voltage detected by the surge voltage detection circuit with the target value.

6. A load power supply circuit configured to connect two gate drive type semiconductor switching elements in series and energize power to an inductive load from a common connection point, the load power supply circuit comprising:
the gate drive device according to claim 1 for driving and controlling the two semiconductor switching elements to turn on and off alternately.
